(19) United States
(12) Patent Application Publication
(10) Pub. No.: US 2026/0329195 A1
(43) Pub. Date: Oct. 22, 2026

(54) HEATER ASSEMBLY, SUBSTRATE SUPPORT AND LITHOGRAPHIC APPARATUS

(71) Applicant: ASML NETHERLANDS B.V., Veldhoven (NL)

(72) Inventors: Dennis Johannes Franciscus HECK, Eindhoven (NL); Frank Pieter Albert VAN DEN BERKMORTEL, Deurne (NL); Niek Jacobus Johannes ROSET, Eindhoven (NL); Edwin Johannes Cornelis BOS, Dommelen (NL); Paolo MASTELLONE, Eindhoven (NL)

(73) Assignee: ASML NETHERLANDS B.V., Veldhoven (NL)

(21) Appl. No.: 19/486,347

(22) PCT Filed: May 7, 2024
(86) PCT No.: PCT/EP2024/062663

§ 371 Date: Nov. 20, 2025

(30) Foreign Application Priority Data
Jun. 6, 2023 (EP) 23177493.6

(51) Int. Cl. G03F 7/00; H05B 1/02; H05B 3/06; H05B 3/48; H10P 72/76

(52) U.S. Cl. CPC G03F 7/70875; G03F 7/70341; H05B 1/0233; H05B 3/06; H05B 3/48; H10P 72/7616; H10P 72/7624; H05B 2203/003; H05B 2203/014

(57) ABSTRACT

A heater assembly for use on a generally cylindrical substrate support, the heater comprising: a first heater section configured to be fixed to a circumferential surface of the substrate support; and a second heater section configured to be fixed to the circumferential surface of the substrate support; wherein a first end portion of the first heater section and a second end portion of the second heater section are configured to overlap in an axial direction of the substrate support when fixed to the circumferential surface. WO

### CROSS-REFERENCE TO RELATED APPLICATIONS

This application claims priority of EP application 23177493.6 which was filed on Jun. 6, 2023 and which is incorporated herein in its entirety by reference.

### FIELD

The present invention relates to a heater assembly for a substrate support that is configured to support a substrate, the substrate support having the heater assembly, a lithographic apparatus including the substrate support, a method of supporting a substrate and a method of manufacturing a device including the method of supporting a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, use a projection system to project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”—direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure.

In a lithographic apparatus it is desirable to control the temperature of one or more parts of the lithographic apparatus. For example, it is desirable to keep the temperature of a part substantially constant in the face of a thermal (e.g., heating and/or cooling) load on the part. Such a thermal load may arise from the supply and/or removal of fluid in an immersion lithographic apparatus. As an example, gas removal may lead to undesirable evaporation of liquid adjacent that gas removal. This can in turn lead to localized cooling. Localized cooling is undesirable because it may lead to thermal contraction of the adjacent part and thereby to possible errors. Localized cooling may occur, for example, in or adjacent to a liquid confinement structure, a substrate support, etc.

Therefore, it has been proposed to provide a heater assembly fixed to the peripheral edge of a substrate support to compensate for thermal (e.g., cooling) loads caused by evaporation of immersion fluid being extracted through extraction channels adjacent the edge of the substrate support.

### SUMMARY

Further improvements in arrangements to control the temperature of the substrate support are desirable. It is desirable, for example, to provide an improved heater assembly, a substrate support having such a heater assembly, a lithographic apparatus having such a substrate support and a method of manufacturing such a heat transfer assembly.

According to a first aspect of the invention, there is provided a heater assembly for use on a generally cylindrical substrate support, the heater comprising:
a first heater section configured to be fixed to a circumferential surface of the substrate support; and
a second heater section configured to be fixed to the circumferential surface of the substrate support;
wherein a first end portion of the first heater section and a second end portion of the second heater section are configured to overlap in an axial direction of the substrate support when fixed to the circumferential surface.

According to a second aspect of the invention, there is provided a substrate support configured to support a substrate, the substrate support comprising the heater assembly according to the first aspect.

According to a third aspect of the invention, there is provided a lithographic apparatus comprising the substrate support according to the second aspect.

According to a fourth aspect of the invention, there is provided a method for supporting a substrate, the method comprising use of the substrate support according to the second aspect.

According to a fifth aspect of the invention, there is provided a method for performing lithography, the method comprising projecting a radiation beam onto a substrate in an exposure operation; wherein the substrate is supported by the substrate support according to the second aspect.

Further embodiments, features and advantages of the present invention, as well as the structure and operation of the various embodiments, features and advantages of the present invention are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts a schematic overview of a lithographic apparatus.

FIG. 2 depicts, in cross-section, a substrate support that is not in accordance with the present invention.

FIG. 3 schematically depicts a substrate support, having a heater assembly, in an inverted position.

FIG. 4 schematically depicts a part of the substrate support of FIG. 3 in an enlarged view.

FIG. 5 schematically depicts a part of a heater assembly according to a first embodiment.

FIG. 6 schematically depicts a part of a heater assembly according to a second embodiment.

FIG. 7 schematically depicts a part of a heater assembly according to a third embodiment.

FIG. 8 schematically depicts a part of a heater assembly according to a fourth embodiment.

FIG. 9 schematically depicts a part of a heater assembly according to a fifth embodiment.

FIG. 10 schematically depicts a part of a heater assembly according to a sixth embodiment.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

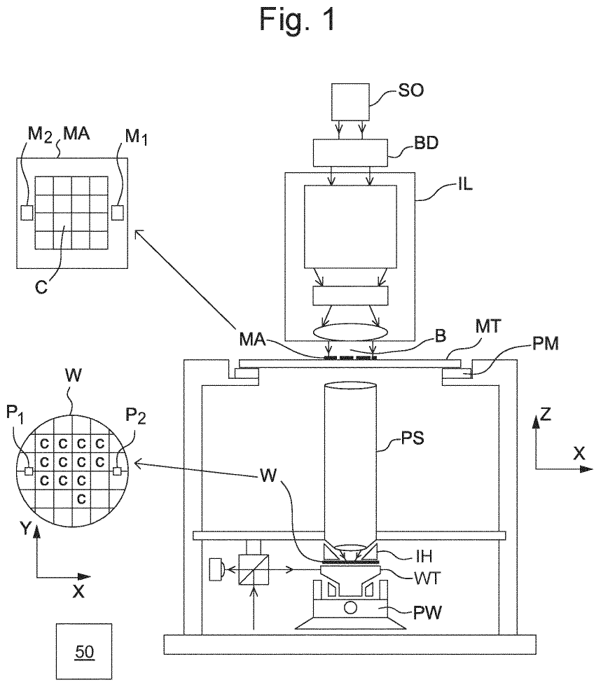

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross-section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space between the final element and a surface facing the final element. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure IH present between the projection system PS and the substrate support WT is used to confine the immersion liquid to the immersion space. The immersion space filled by the immersion liquid is smaller in plan than the top surface of the substrate W and the immersion space remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element. The liquid outside the immersion space is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure IH is a structure which supplies the immersion liquid to the immersion space, removes the immersion liquid from the immersion space and thereby confines the immersion liquid to the immersion space. It includes features which are a part of a fluid supply system. The arrangement disclosed in PCT patent application publication no. WO 99/49504 is an early fluid handling structure comprising pipes which either supply or recover the immersion liquid from the immersion space and which operate depending on the relative motion of the stage beneath the projection system PS. In more recent designs, the fluid handling structure extends along at least a part of a boundary of the immersion space between the final element of the projection system PS and the substrate support WT or substrate W, so as to in part define the immersion space.

The fluid handing structure IH may have a selection of different functions. Each function may be derived from a corresponding feature that enables the fluid handling structure IH to achieve that function. The fluid handling structure IH may be referred to by a number of different terms, each referring to a function, such as barrier member, seal member, fluid supply system, fluid removal system, liquid confinement structure, etc.

Immersion liquid may be used as the immersion fluid. In that case the fluid handling structure IH may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure IH between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element is at least partly surrounded by the fluid handling structure IH. The fluid handling structure IH may confine the immersion liquid under the final element and above the facing surface.

As depicted in FIG. 1, the lithographic apparatus comprises a controller 50. The controller 50 is configured to control the substrate table WT.

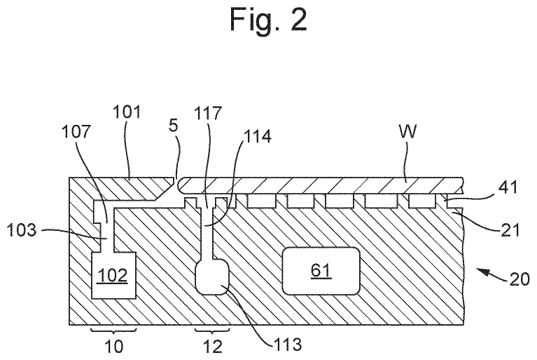

FIG. 2 illustrates part of a known lithographic apparatus that is not in accordance with the present invention. The arrangement illustrated in FIG. 2 and described below may be applied to the lithographic apparatus described above and illustrated in FIG. 1. FIG. 2 is a cross-section through a substrate support 20 and a substrate W. The material of the substrate support 20 is not particularly limited, and could be any suitable material known in the art. Preferably, the substrate support 20 may be made out of silicon infiltrated silicon carbide (SiSiC). Alternatively, the substrate support 20 may be formed of Zerodur™ (a lithium-aluminosilicate glass-ceramic), cordierite, silicon carbide (SiC) or diamond SiSiC. Substrate support 20 is generally cylindrical, e.g. in the form of a flat disc with faces generally perpendicular to the cylindrical axis. Typically, substrate support 2 may have a diameter of 200 mm, 300 mm or 450 mm and a thickness of about 2 to 10 mm.

In an embodiment, the substrate support 20 comprises one or more conditioning channels 61 of a thermal conditioner. A gap 5 exists between an edge of the substrate W and an edge of the substrate support 20. When the edge of the substrate W is being imaged or at other times such as when the substrate W first moves under the projection system PS (as described above), the immersion space filled with liquid by the fluid handling structure IH (for example) will pass at least partly over the gap 5 between the edge of the substrate W and the edge of the substrate support 20. This can result in liquid from the immersion space entering the gap 5.

The substrate W is held by a support body 21 (e.g. a pimple or burl table) comprising one or more burls 41 (i.e., projections from the surface). The support body 21 is an example of an object holder. Another example of an object holder is a mask holder. An under-pressure applied between the substrate W and the substrate support 20 helps ensure that the substrate W is held firmly in place. However, if immersion liquid gets between the substrate W and the support body 21 this can lead to difficulties, particularly when unloading the substrate W.

In order to deal with the immersion liquid entering that gap 5 at least one drain 10, 12 is provided at the edge of the substrate W to remove immersion liquid which enters the gap 5. In the example of FIG. 2, two drains 10, 12 are illustrated though there may only be one drain or there could be more than two drains. In an embodiment, each of the drains 10, 12 is annular so that the whole periphery of the substrate W is surrounded.

A primary function of the first drain 10 (which is radially outward of the edge of the substrate W/support body 21) is to help prevent bubbles of gas from entering the immersion space where the liquid of the fluid handling structure IH is present. Such bubbles may deleteriously affect the imaging of the substrate W. The first drain 10 is present to help avoid gas in the gap 5 escaping into the immersion space in the fluid handling structure IH. If gas does escape into the immersion space, this can lead to a bubble which floats within the immersion space. Such a bubble, if in the path of the projection beam, may lead to an imaging error. The first drain 10 is configured to remove gas from the gap 5 between the edge of the substrate W and the edge of the recess in the substrate support 20 in which the substrate W is placed. The edge of the recess in the substrate support 20 may be defined by a cover ring 101 which is optionally separate from the support body 21 of the substrate support 20. In the x/y plane, the cover ring 101 may be shaped, as a ring that surrounds the outer edge of the substrate W. The first drain 10 extracts mostly gas and only a small amount of immersion liquid.

The second drain 12 (which is radially inward of the edge of the substrate W/support body 21) is provided to help prevent liquid which finds its way from the gap 5 to underneath the substrate W from preventing efficient release of the substrate W from the substrate table WT after imaging. The provision of the second drain 12 reduces or eliminates any problems which may occur due to liquid finding its way underneath the substrate W.

As depicted in FIG. 2, the lithographic apparatus comprises a first extraction channel 102 for the passage therethrough of a two-phase flow. The first extraction channel 102 may be formed within the support body 21 or a component separate from the support body 21. The first and second drains 10, 12 are each provided with a respective opening 107, 117 and a respective extraction channel 102, 113. The extraction channel 102, 113 is in fluid communication with the respective opening 107, 117 through a respective passageway 103, 114.

As depicted in FIG. 2, the cover ring 101 has an upper surface. The upper surface extends circumferentially around the substrate W on the support body 21. In use of the lithographic apparatus, the substrate support 20 moves relative to the fluid handling structure IH. During this relative movement, the fluid handling structure IH passes across the gap 5 between the cover ring 101 and the substrate W. In an embodiment the relative movement is caused by the substrate support 20 moving under the fluid handling structure IH. In an alternative embodiment the relative movement is caused by the fluid handling structure IH moving over the substrate support 20. In a further alternative embodiment, the relative movement is provided by movement of both the substrate support 20 under the fluid handling structure IH and movement of the fluid handling structure IH over the substrate support 20. In the following description, movements of the fluid handling structure IH will be used to mean the relative movement of the substrate support 20 relative to the fluid handling structure IH.

The known design of cover ring 101 has, in plan view, a circular opening for receiving a substrate W. The opening has a fixed diameter. The diameter of the opening is designed so that it is larger than the diameter of the substrate W under all circumstances that can reasonably be expected to occur. If the diameter of the opening is too small, the cover ring 101 may not be usable with a substrate W in all circumstances. The minimum allowable diameter of the opening is dependent on the diameter of the substrate W that the cover ring 101 is designed to surround as well as the required tolerances. The required tolerances include the manufacturing tolerances of the substrate W, the manufacturing tolerances of the opening in the cover ring 101, and any variation in the diameter of the substrate W and the opening in the cover ring 101 during use.

The gap 5 between the cover ring 101 and the substrate W is caused by opening having a larger diameter that the substrate W. In places, the gap 5 may be about 200 μm. When the fluid handling structure IH passes across the gap 5, at least some of the immersion liquid flows through the gap 5. The flow of immersion liquid through the gap 5 increases the thermal loads on the substrate W and substrate support 20.

As discussed above, a thermal load may deleteriously affect the temperature stability of a part of a lithographic apparatus. Such a thermal load is undesirable because it may lead to thermal expansion/contraction of the part (e.g., a substrate support 20, WT or fluid handling structure IH) and thereby lead to possible errors (e.g., overlay errors). A cooling load may arise due to undesirable evaporation of liquid. Such evaporation may occur, for example, due to gas removal through a fluid handling structure IH or by removal of gas through the gap between the substrate W and the substrate support 20. Accordingly, a heater assembly may be provided to control the temperature of a part of a lithographic apparatus.

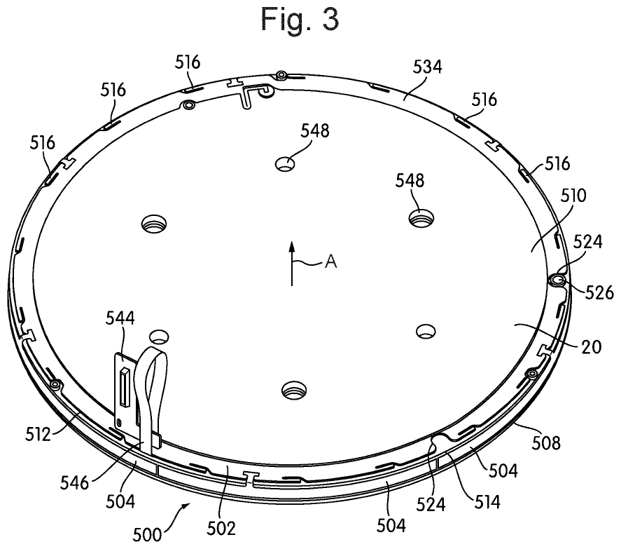

FIG. 3 shows a known heater assembly 500 which is configured to heat a substrate support 20. The heater assembly 500 includes a printed circuit board 502, and a plurality of heater sections 504. The printed circuit board 502 and the plurality of heater sections 504 are configured to be attached to the substrate support 20. The plurality of heater sections 504 are separate from and are electrically coupled to the printed circuit board 502. In other words, the plurality of heater sections 504 are not integrally formed with the printed circuit board 502. In FIG. 3, three heater sections 504 are labelled although six heater sections 504 are shown. Any number of heater sections 504, such as three, four, eight, nine or twelve may be provided.

As shown in FIG. 3, the substrate support 20 includes an upwardly-facing surface 508 and a downwardly-facing surface 510. In an embodiment, the upwardly-facing surface 508 is in the form of a substrate supporting area that is constructed and arranged to support the substrate W (as shown in FIG. 1) on the substrate support 20. The downwardly-facing surface 510 is constructed and arranged to engage with an inner surface 512 of the printed circuit board 502. In other words, the printed circuit board 502 is attached on the downwardly-facing surface 510 of the substrate support 20 that is opposite the upwardly-facing surface 508, i.e., substrate supporting area. Thus, in practice, the heating assembly of FIG. 3 and the substrate support 20 would typically be used in the opposite orientation to that illustrated.

As shown in FIG. 3, the substrate support 20 may generally include a plurality of through holes 548 that enable pins (not shown) to pass therethrough to enable separation of the substrate W from the substrate supporting area of the substrate support 20 and/or that allow an under pressure to be applied to a substrate W supported in use on the substrate supporting area to hold the substrate W on that area.

The printed circuit board 502 may be a flexible printed circuit board. The printed circuit board 502 may include a plurality of attachment members 516 that are constructed and arranged to attach the inner surface 512 (as shown in FIG. 3) of the printed circuit board 502 to the downwardly-facing surface 510 of the substrate support 20. In the illustrated example, the plurality of attachment members 516 may include eighteen attachment members 516 that are generally positioned evenly distributed along the printed circuit board 502. However, the number of attachment members 516 that are generally positioned along the printed circuit board 502 can vary in number.

The printed circuit board 502 may have a plurality of temperature sensors (not shown), e.g. PTC or NTC sensors, to measure the local temperature of the substrate support 20 and enable a desired heating power to be computed for each heater section 504. Desirably there are multiple (e.g. two, three or more) temperature sensors per heater section 504. The temperature sensors can conveniently be located at attachment members 516.

Although not shown, the attachment members 516 may include attachment portions constructed and arranged to engage with engaging members (not shown) located on the downwardly-facing surface 510 (as shown in FIG. 3) of the substrate support 20 to attach the printed circuit board 502 with the substrate support 20.

The printed circuit board 502 may include a plurality of cut-out regions 524 that are constructed and arranged to engage with a plurality of protruding members 526 positioned on the downwardly-facing surface 510 of the substrate support 20 to align and to attach the printed circuit board 502 to the substrate support 20. The plurality of cut-out regions 524 may include two cut-out regions 524, and the plurality of protruding members 526 may include two protruding members 526. However, the number of cut-out regions 524 that are generally positioned on the printed circuit board 502 and the protruding members 526 that are generally positioned on the substrate support 20 can vary in number. The cut-out regions 524 may generally have a semi-circular shaped configuration and the protruding members 526 may generally have a circular shaped configuration. It should be appreciated, however, that this is but one example of different types shapes, configurations and/or constructions of the protruding members 526 and cut-out regions 524 that can be provided.

The printed circuit board 502 may include a power supply terminal 544 constructed and arranged to provide electric power to the printed circuit board 502 and the plurality of heater sections 504. In an embodiment, the power supply terminal 544 is connected to the ring-shaped portion 534 of the printed circuit board 502 using a flexible (or bendable) extension member 546.

The plurality of heater sections 504 of the heater assembly 500 may include six heater sections 504 that are positioned to extend substantially around an edge 514 of the substrate supporting area. However, the number of heater sections 504 that are positioned to extend substantially around the edge 514 of the substrate supporting area can vary in number. Each of the plurality of heater sections 504 may include an arc-shaped configuration. Each heater section 504 may include a heating resistor (not shown) that is constructed and arranged to generate heat, where the amount of heat generated by the heater section 504 is based on the amount of power supplied to the heating resistor. In an embodiment, the heater section 504 may be a cooling device that is constructed and arranged to cause cooling, such as a Peltier element. As such, the heater sections 504 may be described, more generally, as heat transfer elements and the heater assembly as a heat transfer assembly.

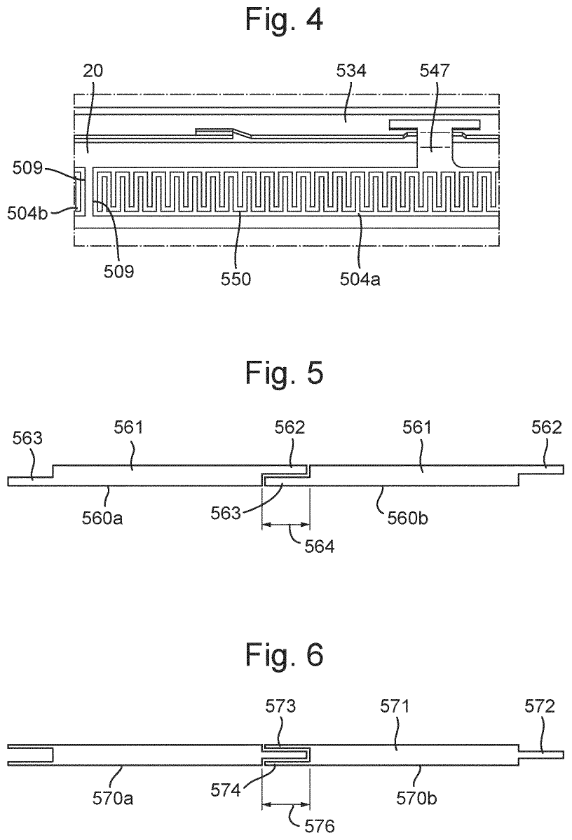

FIG. 4 is an enlarged view of a part of a heater assembly that is similar to the heater assembly 500 of FIG. 3. As shown in FIG. 4, power connection to a heater section 504 is provided by a small tab 547 which connects to the ring-shaped portion 534 of the printed circuit board 502 via a low-profile socket (not shown). Also visible in FIG. 4 is a meandering conductor 550 which forms a heating element to generate heat under control of the controller.

As can clearly be seen in FIG. 4, the opposing ends 509 of adjacent heater sections 504a, 504b are parallel to the axis A (shown in FIG. 3) of the generally cylindrical substrate support 20 (i.e. perpendicular to the support plane for the substrate W that is defined by the burls 41 of the substrate support 20) and separated by a small gap. Since the individual heater sections 504 of the heater assembly 500 are individually controlled according to the heating load required to maintain the respective regions of the substrate support 20 at the temperature set point, it can occur that adjacent ones of the heater sections 504 may generate different amounts of power. In an extreme case, one heater section 504 may be on full power and an adjacent heater section 504 may be off. Differences in the heating power applied to the substrate support 20 by adjacent heater sections 504 cause thermal gradients in the vicinity of the gap between adjacent heater sections 504. The gap may be of the order of 1-2 mm. In spite of the high thermal conductivity of the substrate support 20, there may be sufficiently large thermal gradients to cause distortions and/or stress in the substrate support 20 and a substrate W held by the substrate support 20. Such stresses and distortions may lead to imaging errors, e.g. overlay. A temperature gradient of a few tenths of a Kelvin per mm may be enough to cause errors. It is desirable to reduce or eliminate such errors.

FIG. 5 depicts schematically two heater sections 560a, 560b according to an embodiment of the present invention. Each of the heater sections 560a, 560b comprises a main part 561 that, when the heater section 560a, 560b is mounted to the substrate support 20, extends along the cylindrical surface thereof. At each end of the main portion 561 there are projecting portions 562, 563, which have a width in the direction parallel to the axial direction of the substrate support that is less than the width in that direction of the main portion 561. A first projecting portion 562 of the projecting portions 562, 563 is provided at an upper side of first end of the main portion 561 whilst a second projecting portion 563 of the projecting portions 562, 563 is provided at a lower side of a second end of the main portion 561. The first projecting portion 562 and the second projecting portion 563 are complementary.

When the heater sections 560a, 560b are installed on the substrate support 20 the first and second projecting portions 562, 563 overlap in the axial direction of the substrate support 20. Desirably, the widths of the first and second projecting portions 562, 563 in the axial direction are equal. Desirably the sum of the widths in the axial direction of the first and second projecting portions 562, 563 is substantially equal to the width of the main portion 561, allowing for a small gap to accommodate tolerance in installation and to ensure electrical separation of the first and second heater sections 562, 563. Desirably the heating power applied by the heater sections 560a, 560b per unit area is substantially uniform across the whole area of the heater sections 560a, 560b.

With the structure illustrated in FIG. 5, it will be appreciated that if the first and second heater sections 560a, 560b are operating with different powers there will not be a sharp transition between the regions receiving different heating power but rather an intermediate region, referred to herein as the overlap region, that receives an average amount of power. For example, first heater section 560a is at full power and second section 560b is at zero power the overlap region 564 will receive half power. This arrangement thereby reduces temperature gradients in the substrate support 20 and hence reduces distortion and stresses in a substrate W held by the substrate support 20.

Another embodiment is shown in in FIG. 6 which differs from the arrangement of FIG. 5 only in the arrangement to reduce temperature gradients in the substrate support 20 and hence reduce the distortion and stresses in a substrate W held by a substrate support 20. Specifically, the embodiment shown in FIG. 6 has heater sections 570c, 570b with a different arrangement of projecting portions 572, 573, 574 at the ends of the main portion 571 of the heater sections 570a, 570b. In the arrangement of FIG. 6, one end of each heater section 570a, 570b has a centrally positioned projecting portion 572 projecting from main part 571. The other end of heater section 570a, 570b has two projecting portions 573, 574 arranged at the top and bottom ends of the end side of the main portion 571. The first projecting portion 572 is complementary to the second and third projecting portions 573, 574. Thus, when the heater sections 570a, 570b are fixed to the cylindrical surface of the substrate support 20, the first projection 572 of heater section 570a fits between the second and third projections 573, 574 of second heater section 570b. The arrangement of FIG. 6 has the same effect as the arrangement of FIG. 5, namely that when heater sections 570a, 570b apply different heating powers, overlap region 576 applies an intermediate amount of heating power so that thermal gradients in the circumferential direction are reduced. The arrangement of FIG. 6 provides an additional advantage in that thermal gradients in the axial direction are also reduced.

It will be appreciated that a variety of other shapes can be applied to end portions of heater sections so as to create an overlap in the axial direction between adjacent heater sections.

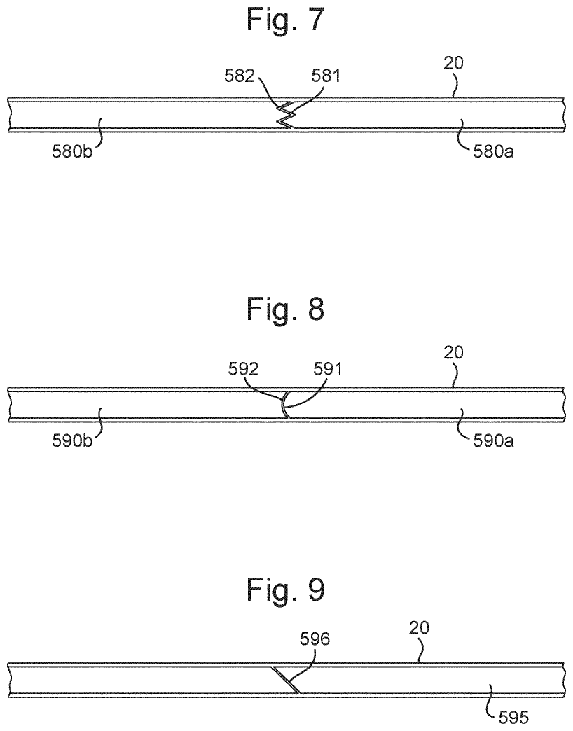

Some further examples are shown in FIGS. 7 to 10 but yet further arrangements may of course be devised based on the teaching set out herein.

FIG. 7 depicts an arrangement wherein the ends of adjacent heater sections 580a, 580b have complementary triangular projections 581, 582 that interleave. This arrangement has an advantage that the heating power provided in the overlap region changes gradually in the circumferential direction rather than changing in a stepped fashion and therefore any thermal gradients are further reduced.

FIG. 8 depicts an arrangement in which the ends of adjacent heater sections 590a, 590b have complementary curved edges 591, 592. One end of each intersection has a convex curved edge 591 and the other end has a concave curved edge 592 of complementary profile. Similarly, to the arrangement of FIG. 7, the arrangement of FIG. 8 can provide a more gradual transition in heating power.

FIG. 9 depicts an arrangement whereby each heater section 595 has a parallelogram shape with end edges 596 that are inclined to the axial direction of the substrate support when affixed to the cylindrical surface thereof. The parallelogram shape may be considered as a rectangular main region and two triangular projections. Similarly, to the arrangements of FIGS. 7 and 8, a gradual transition of heater power through the overlap zone can thereby be achieved.

From the above examples, which may of course be combined as desired, it will be appreciated that the temperature transition between adjacent heater sections providing different powers can be smoothed in any way desirably, subject to manufacturing convenience.

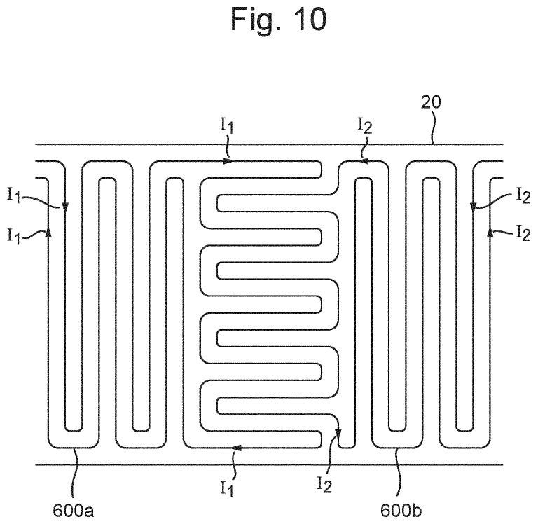

FIG. 10 shows a similar effect can be achieved by interleaving meandering heating wires 600a, 600b that can be attached to a common heater substrate or directly to the substrate support. The currents I₁, I₂ flowing in the heating wires 600a, 600b respectively are individually controllable. In an embodiment, the main part of each heater section has a meandering heating wire that has long vertical runs extending from top to bottom of the heater section and connected by short horizontal runs. In an overlap zone, each heater section has a plurality of horizontal extensions or fingers that are interleaved (or interdigitated) with the extensions of an adjacent heater sections. The overlapping portion may be considered to resemble two interlocking combs. The parts of the meandering heating wires 600a, 600b that interleave with a meandering heating wire 600a, 600b of an adjacent heater section may be regarded as projecting portions. In this arrangement, to avoid overheating the overlap portion, the thickness (and hence resistance per unit length) of the heating wires 600a, 600b may be adjusted in the overlap portion. Alternatively, where there are many meanders in the heating wire 600a, 600b of each heater section, only some meanders may be interleaved with the adjacent heater section. Other arrangements, such as a Greek key pattern or interlocked spirals are also possible.

It will be appreciated that the size of the overlap region may depend, for example, on the number of heater sections that are provided around the substrate support 20. Where there are more heater segments, it is likely that the difference between the power applied by adjacent heater segments will be less and so a smaller overlap section may be sufficient. However, overall, it is desirable that the total of the lengths in the circumferential direction of the overlap sections is between about 10% and about 600% of the circumference of the substrate support 20, desirably between about 20% and 50%.

To simplify manufacturing and assembly, it is desirable that all of the heater sections are identical. This means that one end of each heater section should be complimentary to the other end of each heater section. In some arrangements, it is desirable that the heater sections have 180 degree rotational symmetry.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate support WT, etc ..

Specifically, the lithographic apparatus may comprise the projection system PS configured to project the radiation beam B towards the region of the surface of a substrate W. The lithographic apparatus may further comprise the substrate support 300, 400, 500 as described in any of the above embodiments and variations.

Embodiments include the following numbered clauses:
1. A heater assembly for use on a generally cylindrical substrate support, the heater comprising:
   a first heater section configured to be fixed to a circumferential surface of the substrate support; and
   a second heater section configured to be fixed to the circumferential surface of the substrate support;
   wherein a first end portion of the first heater section and a second end portion of the second heater section are configured to overlap in an axial direction of the substrate support when fixed to the circumferential surface.
2. The heater assembly according to clause 1, wherein:
   the first heater section has a first main portion and the first end portion comprises a first projecting portion having a width in the axial direction that is less than the first main portion; and
   the second heater section has a second main portion and the second end portion comprises a second projecting portion having a width in the axial direction that is less than the second main portion, the first and second projecting portions being configured so that they are adjacent in the axial direction when fixed to the circumferential surface.
3. The heater assembly according to clause 2, wherein the first and second projecting portions have equal widths in the axial direction.
4. The heater assembly according to clause 2, wherein the second end portion further comprises a third projecting portion having a width in the axial direction that is less than the second main portion, the first, second and third projecting portions being configured so that the first projecting portion is between the second and third projecting portions in the axial direction when fixed to the circumferential surface.
5. The heater assembly according to clause 4, wherein the width of the first projecting portion in the axial direction is substantially equal to the sum of the widths in the axial direction of the second and third projecting portions.
6. The heater assembly according to any preceding clause, wherein an edge of each of the first and second end portions is inclined at an acute angle to the axial direction.
7. The heater assembly according to clause 6, wherein the acute angle is in the range of from 20° to 70°, desirably in the range of from 30° to 60°.
8. The heater assembly according to any preceding clause, wherein an edge of each of the first and second end portions is curved.
9. The heater assembly according to any preceding clause, wherein each of the first and second heater sections comprises a meandering heating wire.
10. The heater assembly according to clause 9, wherein a part of the meandering heating wire of the first heater section is interleaved with a part of the meandering heating wire of the second heater section.
11. The heater assembly according to clause 9 or 10, wherein the meandering heating wires have a heating power per unit length that varies along the length thereof.
12. The heater assembly according to any preceding clause, wherein the first heater section has a second end portion that corresponds in shape to the second end portion of the second heater section and the second heater section has a first end portion that corresponds in shape to the first end portion of the first heater section.
13. The heater assembly according to any preceding clause, comprising 4, desirably 8, heater sections.
14. The heater assembly according to any preceding clause, wherein the number of heater sections is less than 16, desirably less than 12.
15. The heater assembly according to any preceding clause, wherein the heater sections are independently controllable.
16. The heater assembly according to any preceding clause, wherein the heater sections are substantially identical.
17. A substrate support configured to support a substrate, the substrate support comprising a generally cylindrical main body and the heater assembly according to any preceding clause wherein the first and second heater sections are fixed to the circumferential surface of the substrate support.
18. A substrate support according to clause 16, wherein the main body is formed of silicon infiltrated silicon carbide (SiSiC), a lithium-aluminosilicate glass-ceramic, Zerodur, cordierite, silicon carbide (SiC) or diamond SiSiC.
19. A lithographic apparatus comprising the substrate support according to clause 17 or 18.
20. The lithographic apparatus according to clause 19, further comprising a control system arranged to independently control the heat outputs of the heater sections.
21. A method for performing lithography, the method comprising projecting a radiation beam onto a substrate in an exposure operation;
   wherein the substrate is supported by the substrate support according to clause 17 or 18.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A heater assembly for use on a generally cylindrical substrate support, the heater comprising:
a first heater section configured to produce heat and to be fixed to a circumferential surface of the substrate support; and
a second heater section configured to produce heat and to be fixed to the circumferential surface of the substrate support,
wherein a first end portion of the first heater section and a second end portion of the second heater section are configured to overlap in an axial direction of the substrate support when fixed to the circumferential surface and wherein the first heater section overlaps in the axial direction less than the entirety of the second heater section when the first and second heater sections are fixed to the circumferential surface.

2. The heater assembly according to claim 1, wherein:
the first heater section has a first main portion and the first end portion comprises a first projecting portion having a width in the axial direction that is less than a width of the first main portion in the axial direction; and
the second heater section has a second main portion and the second end portion comprises a second projecting portion having a width in the axial direction that is less than a width of the second main portion in the axial direction,
the first and second projecting portions being configured so that they are adjacent in the axial direction when fixed to the circumferential surface.

3. The heater assembly according to claim 2, wherein the first and second projecting portions have equal widths in the axial direction.

4. The heater assembly according to claim 1, wherein an edge of each of the first and second end portions is inclined at an acute angle to the axial direction.

5. The heater assembly according to claim 4, wherein the acute angle is in the range of from 20° to 70°.

6. The heater assembly according to claim 1, wherein the first heater section has a second end portion that corresponds in shape to the second end portion of the second heater section and the second heater section has a first end portion that corresponds in shape to the first end portion of the first heater section.

7. The heater assembly according to claim 1, comprising heater sections, and/or wherein the number of heater sections is less than 16.

8. The heater assembly according to claim 1, wherein the heater sections are independently controllable, and/or wherein the heater sections are substantially identical.

9. A substrate support configured to support a substrate, the substrate support comprising a generally cylindrical main body and the heater assembly according to claim 1, wherein the first and second heater sections are fixed to the circumferential surface of the substrate support.

10. The substrate support according to claim 9, wherein the main body is formed of silicon infiltrated silicon carbide (SiSiC), a lithium-aluminosilicate glass-ceramic, Zerodur ceramic, cordierite, silicon carbide (SiC) or diamond SiSiC.

11. A lithographic apparatus comprising the substrate support according to claim 9.

12. The lithographic apparatus according to claim 11, further comprising a control system arranged to independently control the heat outputs of the heater sections.

13. A method for performing lithography, the method comprising projecting a radiation beam onto a substrate in an exposure operation, wherein the substrate is supported by the substrate support according to claim 9.

14. The heater assembly according to claim 1, wherein an edge of each of the first and second end portions is curved.

15. The heater assembly according to claim 1, wherein each of the first and second heater sections comprises a meandering heating wire.

16. The heater assembly according to claim 15, wherein a part of the meandering heating wire of the first heater section is interleaved with a part of the meandering heating wire of the second heater section, and/or wherein the meandering heating wires have a heating power per unit length that varies along the length thereof.

17. The heater assembly according to claim 2, wherein the second end portion further comprises a third projecting portion having a width in the axial direction that is less than the second main portion, the first, second and third projecting portions configured so that the first projecting portion is between the second and third projecting portions in the axial direction when fixed to the circumferential surface.

18. The heater assembly according to claim 17, wherein the width of the first projecting portion in the axial direction is substantially equal to the sum of the widths in the axial direction of the second and third projecting portions.

19. A heater assembly for use on a generally cylindrical substrate support, the heater comprising:
at least three heater sections, each configured to produce heat and to be fixed to a circumferential surface of the substrate support,
wherein an end portion of each heater section is configured to overlap in an axial direction of the substrate support, when the heater sections are fixed to the circumferential surface, with an end portion of an adjacent other heater section.

20. The heater assembly according to claim 19, wherein:
the end portion of each heater section comprises a first projecting portion having a width in the axial direction that is less than a width of a main portion of that heater section in the axial direction; and
the end portion of the adjacent other heater section comprises a second projecting portion having a width in the axial direction that is less than a width of a main portion of that adjacent other heater section in the axial direction,
the first and second projecting portions being configured so that they are adjacent in the axial direction when fixed to the circumferential surface.
